(19) United States
(12) Patent Application Publication
(10) Pub. No.: US 2025/0253159 A1
(43) Pub. Date: Aug. 7, 2025

(54) METHOD OF MANUFACTURING SEMICONDUCTOR DEVICE, APPARATUS FOR MANUFACTURING SEMICONDUCTOR DEVICE, AND SEMICONDUCTOR DEVICE

(71) Applicant: Tokyo Electron Limited, Tokyo (JP)

(72) Inventors: Seishin YAMADA, Nirasaki-shi (JP); Yuki KIKUCHI, Nirasaki-shi (JP); Hisashi WARASHINA, Tokyo (JP)

(21) Appl. No.: 19/189,323

(22) Filed: Apr. 25, 2025

Related U.S. Application Data
(63) Continuation of application No. PCT/JP2023/038672, filed on Oct. 26, 2023.

(30) Foreign Application Priority Data
Nov. 4, 2022 (JP) 2022-177410

(51) Int. Cl. H01L 21/3205; H10B 12/00

(52) U.S. Cl. CPC H01L 21/3205; H10B 12/01

(57) ABSTRACT

A method of manufacturing a semiconductor device including an insulating layer, an adhesion layer composed of a titanium nitride, and a metal layer, includes: forming the adhesion layer on the insulating layer; forming the metal layer on the adhesion layer; and performing a thermal processing on the insulating layer, the adhesion layer, and the metal layer, wherein, in the forming of the adhesion layer, a composition ratio of nitrogen to titanium in the titanium nitride constituting the adhesion layer is 0.6 or more.

### CROSS-REFERENCE TO RELATED APPLICATIONS

This application is a bypass continuation application of International Application No. PCT/J P2023/038672 having an international filing date of Oct. 26, 2023 and designating the United States, the international application being based upon and claiming the benefit of priority from Japanese Patent Application No. 2022-177410, filed on Nov. 4, 2022, the entire contents of which are incorporated herein by reference.

### TECHNICAL FIELD

The present disclosure relates to a method of manufacturing a semiconductor device, an apparatus for manufacturing the semiconductor device, and the semiconductor device.

### BACKGROUND

In recent years, miniaturization of wiring in a semiconductor device, for example, a dynamic random access memory (DRAM) has been progressed. Further, as a material of the wiring, ruthenium (Ru) or molybdenum (Mo), which is a high melting point metal, is used instead of tungsten (W) which has been widely used in the related art. Titanium nitride (TiN) is used as a material of an adhesion layer for ruthenium or molybdenum. In particular, an increase in resistivity due to a fine line effect is suppressed. Accordingly, ruthenium frequently used in a semiconductor wiring process is suitably used as the material of the wiring.

In the DRAM, the wiring made of ruthenium is formed on, for example, an interlayer insulating film made of silicon dioxide (SiO₂). At this time, in order to suppress the wiring from being separated from the interlayer insulating film, the adhesion layer made of titanium nitride is provided between the wiring and the interlayer insulating film (for example, see Patent Document 1).

### PRIOR ART DOCUMENTS

### Patent Documents

Patent Document 1: Japanese Patent Laid-Open Publication No. 2012-253148

### SUMMARY

According to one embodiment of the present disclosure, a method of manufacturing a semiconductor device including an insulating layer, an adhesion layer composed of a titanium nitride, and a metal layer, includes: forming the adhesion layer on the insulating layer; forming the metal layer on the adhesion layer; and performing a thermal processing on the insulating layer, the adhesion layer, and the metal layer, wherein, in the forming of the adhesion layer, a composition ratio of nitrogen to titanium in the titanium nitride constituting the adhesion layer is 0.6 or more.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view schematically illustrating a configuration of an example of test pieces for examining a cause of a degradation in etching processability of a metal layer due to a high-temperature thermal processing.

FIG. 2A is an example of electrophotographs showing a result of a cross-sectional composition analysis of a test piece on which a low-temperature thermal processing or a high-temperature thermal processing is performed.

FIG. 2B is an example of electrophotographs showing a result of the cross-sectional composition analysis of the test piece on which a low-temperature thermal processing or a high-temperature thermal processing is performed.

FIG. 3A is a cross-sectional view schematically illustrating a configuration of an example of a test piece for examining a cause of diffusion of titanium from a titanium nitride layer.

FIG. 3B is a cross-sectional view schematically illustrating a configuration of an example of a test piece for examining a cause of diffusion of titanium from a titanium nitride layer.

FIG. 4A is an example of electrophotographs showing a result of a cross-sectional composition analysis of each test piece before and after the high-temperature thermal processing.

FIG. 4B is an example of electrophotographs showing a result of a cross-sectional composition analysis of each test piece before and after the high-temperature thermal processing.

FIG. 5A is a graph showing a distribution state of each atom in a depth direction on a cross-section of each test piece before and after the high-temperature thermal processing.

FIG. 5B is a graph showing a distribution state of each atom in a depth direction on a cross-section of each test piece before and after the high-temperature thermal processing.

FIG. 6A is a schematic view illustrating diffusion of titanium or nitrogen before and after the high-temperature thermal processing.

FIG. 6B is a schematic view illustrating diffusion of titanium or nitrogen before and after the high-temperature thermal processing.

FIG. 7 is a graph showing a resistivity of a ruthenium layer in each test piece after the high-temperature thermal processing.

FIG. 8 is a partial cross-sectional view schematically illustrating an example of a configuration of a DRAM as a semiconductor device, to which a technique according to the present disclosure is applied.

FIG. 9A is a process view illustrating an example of a method of manufacturing a portion of the DRAM to which the technique according to the present disclosure is applied.

FIG. 9B is a process view illustrating an example of a method of manufacturing a portion of the DRAM to which the technique according to the present disclosure is applied.

FIG. 9C is a process view illustrating an example of a method of manufacturing a portion of the DRAM to which the technique according to the present disclosure is applied.

FIG. 9D is a process view illustrating an example of a method of manufacturing a portion of the DRAM to which the technique according to the present disclosure is applied.

FIG. 9E is a process view illustrating an example of a method of manufacturing a portion of the DRAM to which the technique according to the present disclosure is applied.

FIG. 10 is a view schematically illustrating a configuration of an example of a PVD apparatus for forming a titanium nitride layer.

FIG. 11 is a view schematically illustrating a configuration of an example of a thermal processing apparatus that performs a first thermal processing or a second thermal processing.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a process of manufacturing a DRAM, a metal layer constituting an adhesion layer or wiring may be formed on an interlayer insulating layer, and subsequently, a high-temperature thermal processing may be performed on the adhesion or the metal layer at a temperature of, for example, 950 degrees C. In this case, it was confirmed by the inventors that processability of reactive ion etching of the metal layer subjected to the high-temperature thermal processing was degraded, and a resistivity of the metal layer was degraded (increased).

In order to complement such a degradation in the processability of the metal layer, it is conceivable to utilize, for example, physical etching using argon (Ar). However, since there is a risk that the physical etching will damage a mask or an insulating layer, which is formed on the metal layer, it is preferable that the physical etching is not used in the process of manufacturing the DRAM.

Thus, a technique according to the present disclosure prevents the degradation in etching processability of a metal layer or the degradation in resistivity of the metal layer by adjusting a composition of titanium nitride constituting an adhesion layer.

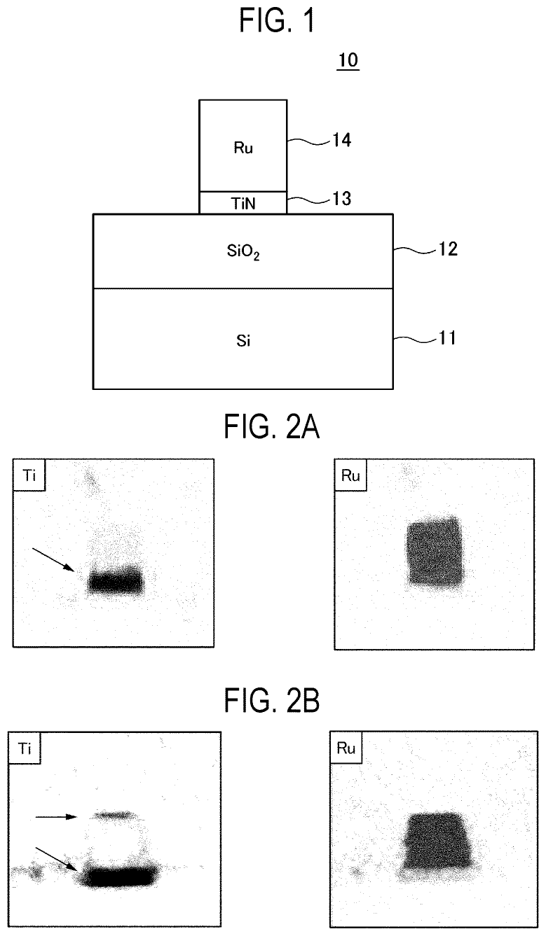

Hereinafter, an embodiment of the technique according to the present disclosure will be described with reference to the drawings. First, the inventors manufactured two test pieces as samples so as to examine a cause of the degradation in etching processability of the metal layer due to a high-temperature thermal processing. FIG. 1 is a cross-sectional view schematically illustrating a configuration of an example of two test pieces. In a test piece 10 shown in FIG. 1, a silicon dioxide (SiO₂) film 12 as an insulating film is formed on a silicon substrate 11, and a titanium nitride (TiN) layer 13 as an adhesion layer is formed on the silicon dioxide film 12. Further, a ruthenium (Ru) layer 14 as a metal layer is formed on the titanium nitride layer 13.

Subsequently, the inventors prepared, for example, a test piece 10 on which a low-temperature thermal processing was performed at 400 degrees C., and a test piece 10 on which a high-temperature thermal processing was performed, and performed reactive ion etching for processing the ruthenium layer 14 on each of the test pieces 10. At this time, it was confirmed that while processability of the ruthenium layer 14 of the test piece 10 on which the low-temperature thermal processing was performed was satisfactory, processability of the ruthenium layer 14 of the test piece 10 on which the high-temperature thermal processing was performed was degraded.

Subsequently, the inventors observed cross-sections of the test piece 10 on which the low-temperature thermal processing was performed and the test piece 10 on which the high-temperature thermal processing was performed. In the observation of these cross-sections, a composition analysis was performed by a transmission electron microscope (TEM)/energy dispersive X-ray (EDX) analysis.

FIGS. 2A and 2B are examples of electrophotographs showing results of a cross-sectional composition analysis of the test piece 10 on which the low-temperature thermal processing or the high-temperature thermal processing was performed. FIG. 2A shows a distribution of titanium in the titanium nitride layer 13 or a distribution of ruthenium in the ruthenium layer 14 in the test piece 10 on which the low-temperature thermal processing was performed. FIG. 2A shows a distribution of titanium or nitrogen in the titanium nitride layer 13 or a distribution of ruthenium in the ruthenium layer 14 in the test piece 10 on which the high-temperature thermal processing was performed. Further, in each electrophotograph in FIGS. 2A and 2B, “Ti” represents titanium and “Ru” represents ruthenium.

As illustrated in FIG. 2A, in the test piece 10 on which the low-temperature thermal processing was performed, titanium (see arrow) in the titanium nitride layer 13 stays below the ruthenium layer 14 to be stabilized. Meanwhile, as illustrated in FIG. 2B, in the test piece 10 on which the high-temperature thermal processing was performed, it was confirmed that titanium (see arrows) in the titanium nitride layer 13 was separated into two layers be being diffused with the ruthenium layer 14 interposed therebetween. Further, it was naturally considered that since the titanium in the titanium nitride layer 13 was separated into the two layers due to the diffusion with the ruthenium layer 14 interposed therebetween, the titanium diffused from the titanium nitride layer 13 exists in the ruthenium layer 14.

That is, the titanium does not exist in the ruthenium layer 14 of the test piece 10 having the satisfactory processability of etching, on which the low-temperature thermal processing was performed. Meanwhile, the diffused titanium exists in the ruthenium layer 14 of the test piece 10 having the degraded etching processability, on which the high-temperature thermal processing was performed. As described above, the cause of the degradation in etching processability of the ruthenium layer 14 due to the high-temperature thermal processing is considered to be that the diffused titanium exists in the ruthenium layer 14.

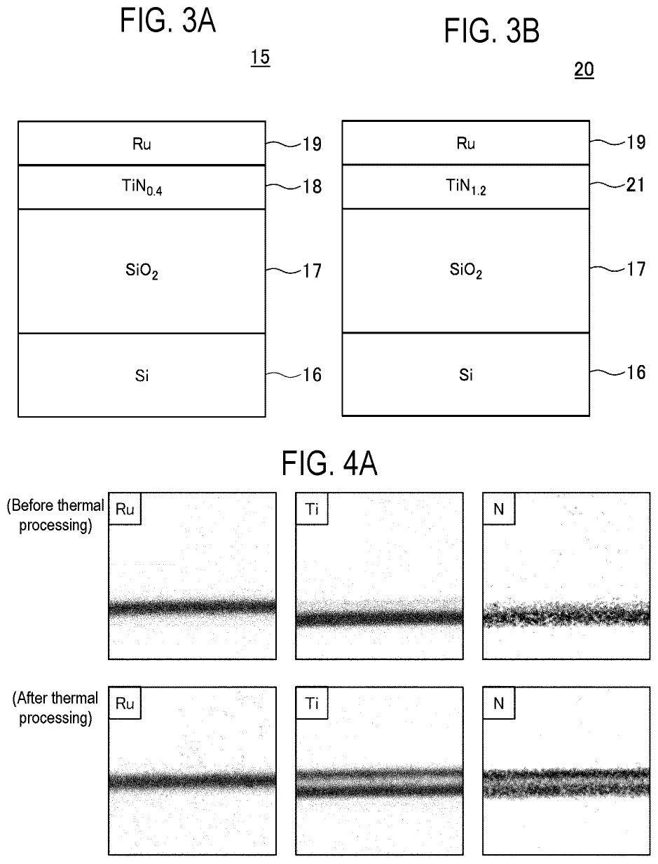

Accordingly, in order to examine the cause of the diffusion of the titanium from the titanium nitride layer, the inventors manufactured two new test pieces as samples. FIGS. 3A and 3B are cross-sectional views schematically illustrating configurations of examples of two test pieces.

In a test piece 15 shown in FIG. 3A, a silicon dioxide film 17 as an insulating film is formed on a silicon substrate 16, and a titanium nitride layer 18 as an adhesion layer is formed on the silicon dioxide film 17 by physical vapor deposition (PVD). Further, a ruthenium layer 19 as a metal layer is formed on the titanium nitride layer 18 by PVD. A film thickness of the titanium nitride layer 18 is 5 nm, a composition ratio (atom number ratio) of nitrogen to titanium is 0.4, and a film thickness of the ruthenium layer 19 is 20 nm. Like the test piece 15, in a test piece 20 shown in FIG. 3B, a silicon dioxide film 17 is formed on a silicon substrate 16, and a titanium nitride layer 21 is formed on the silicon dioxide film 17 by PVD. Further, a ruthenium layer 19 is formed on the titanium nitride layer 21. A film thickness of the titanium nitride layer 21 is also 5 nm, but a composition ratio of nitrogen to titanium in the titanium nitride layer 21 is 1.2. That is, since the test piece 15 and the test piece 20 have different composition ratios of nitrogen to titanium in the titanium nitride layers, the titanium nitride layer 18 of the test piece 15 is in a titanium rich state, and the titanium nitride layer 21 of the test piece 20 is in a nitrogen rich state. In addition, a subscript of “TiN” in the drawing represents a composition ratio of nitrogen to titanium in a titanium nitride layer. The same applies to the following.

Further, the inventors observed cross-sections before and after the high-temperature thermal processing by performing the high-temperature thermal processing on the test piece 15 and the test piece 20. In the high-temperature thermal processing, under an atmosphere in which a flow rate ratio of nitrogen (N₂) gas was 96% and a flow rate ratio of hydrogen (H₂) gas was 4%, temperatures of the test piece 15 and the test piece 20 were maintained at 950 degrees C. for one minutes. Further, in the cross-section observation, a composition analysis is performed by a TEM/EDX analysis.

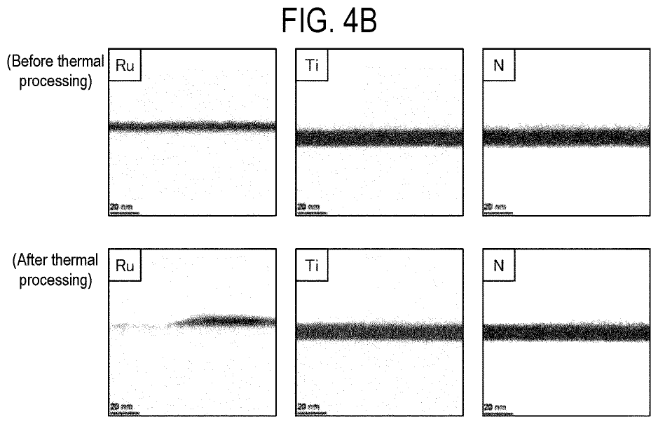

FIGS. 4A and 4B are examples of electrophotographs showing results of a cross-sectional composition analysis of each test piece before and after the high-temperature thermal processing. FIG. 4A shows a distribution or titanium or nitrogen in the titanium nitride layer 18 of the test piece 15 and a distribution of ruthenium in the ruthenium layer 19 of the test piece 15. FIG. 4B shows a distribution or titanium or nitrogen in the titanium nitride layer 21 of the test piece 20 and a distribution of ruthenium in the ruthenium layer 19 of the test piece 20. Further, in each electrophotograph in FIGS. 4A and 4B, “Ru” represents ruthenium, “Ti” represents titanium, and “N” represents nitrogen.

As illustrated in FIG. 4A, in the test piece 15, it was confirmed that after the high-temperature thermal processing, titanium or nitrogen in the titanium nitride layer 18 was separated into two layers be being diffused with the ruthenium layer 19 interposed therebetween. Meanwhile, as illustrated in FIG. 4B, in the test piece 20, it was confirmed that after the high-temperature thermal processing, titanium or nitrogen in the titanium nitride layer 21 was stabilized without diffusion.

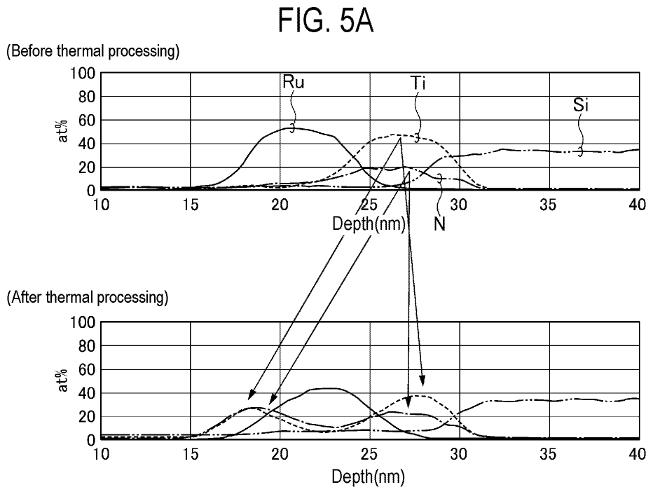

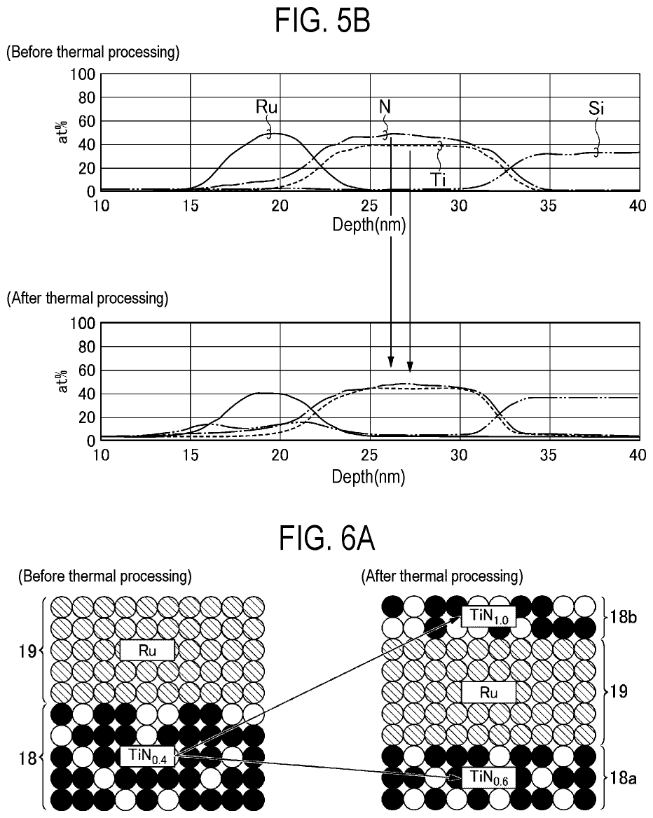

FIGS. 5A and 5B are graphs showing distribution states of each atom in a depth direction on a cross-section of each test piece before and after the high-temperature thermal processing, and each graph was obtained by scan of EDX. In FIGS. 5A and 5B, the vertical axis represents a composition ratio (atom number ratio: at %) of each atom, and the horizontal axis represents a depth in each test piece. Further, in each graph of FIGS. 5A and 5B, “Ru” represents ruthenium, a distribution state of ruthenium is indicated by a solid line, “Ti” represents titanium, and a distribution state of titanium is indicated by a broken line. Further, in each graph of FIGS. 5A and 5B, “N” represents nitrogen, a distribution state of nitrogen is indicated by an alternated long and short dash line, “Si” represents silicon, and a distribution state of silicon is indicated by an alternate long and two short dashes line. FIG. 5A shows a distribution state of each atom in the test piece 15, and FIG. 5B shows a distribution state of each atom in the test piece 20.

As illustrated in FIG. 5A, in the test piece 15, it was confirmed that after the high-temperature thermal processing, titanium or nitrogen in the titanium nitride layer 18 was separated into two layers by being diffused with ruthenium in the ruthenium layer 19 interposed therebetween. Further, it was recognized that in the graph after the high-temperature thermal processing in FIG. 5A, a composition ratio of titanium represented about 10% even in the vicinity of a depth of 22 nm to 23 nm, in which the ruthenium layer 19 was located, and hence the titanium existed in the ruthenium layer 19. Meanwhile, as illustrated in FIG. 5B, in the test piece 20, it was confirmed that after the high-temperature thermal processing, titanium or nitrogen in the titanium nitride layer 21 was stabilized while being located below the ruthenium layer 19 without being diffused.

As described above, from the results of the composition analysis, which are shown in FIGS. 4A and 4B, or the distribution states of each atom, which are shown in FIGS. 5A and 5B, the inventors have found that titanium or nitrogen in the titanium nitride layer may be diffused by the high-temperature thermal processing according to the composition ratio of nitrogen to titanium in the titanium nitride layer. Specifically, the inventors have found that titanium or nitrogen in the titanium nitride layer is diffused by the high-temperature thermal processing when the composition ratio of nitrogen to titanium is 0.4, and is not diffused by the high-temperature thermal processing when the composition ratio of nitrogen to titanium is 1.2.

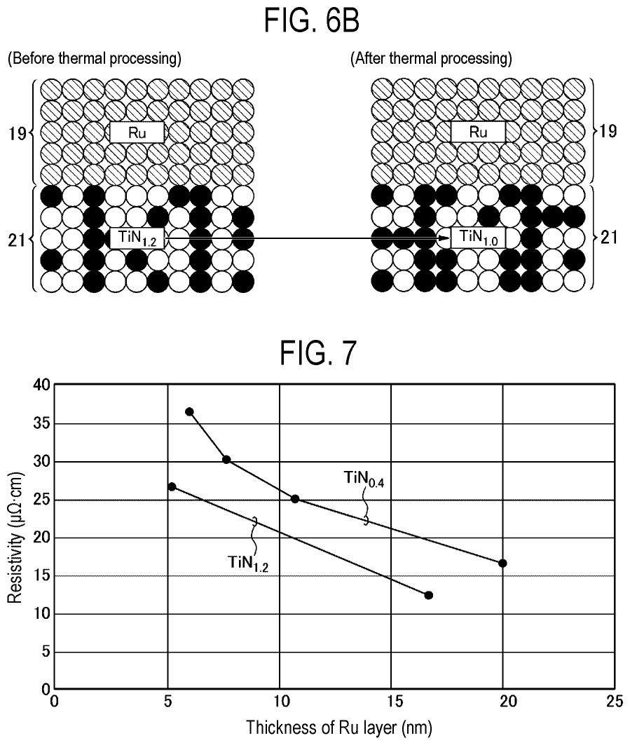

FIGS. 6A and 6B are schematic views illustrating diffusion of titanium or nitrogen before and after the high-temperature thermal processing, FIG. 6A showing a case of the test piece 15, and FIG. 6B showing a case of the test piece 20. Further, in these figures, a hatched circle indicates a ruthenium atom, a black circle indicates a titanium atom, and a white circle indicates a nitrogen atom.

The inventors measured a composition ratio of nitrogen to titanium in the titanium nitride layer composed of titanium or nitrogen, which is separated into two layers in the test piece 15 after the high-temperature thermal processing. As a result, it was confirmed that a composition ratio of nitrogen to titanium in a lower titanium nitride layer 18a that remains below the ruthenium layer 19 was changed from 0.4 to 0.6. Further, it was confirmed that a composition ratio of nitrogen to titanium in an upper titanium nitride layer 18b that moves above the ruthenium layer 19 was 0.1 (FIG. 6A). In other words, it was confirmed that in the test piece 15, titanium was relatively decreased at a lower side of the ruthenium layer 19 when the titanium nitride layer 18 was changed to the lower titanium nitride layer 18a by the high-temperature thermal processing. Further, it was confirmed that nitrogen was increased at an upper side of the ruthenium layer 19 as compared with the titanium nitride layer 18 when the upper titanium nitride layer 18b was formed by the high-temperature thermal processing.

From the confirmed relatively decrease in titanium in the lower titanium nitride layer 18a or the confirmed increase in nitrogen in the upper titanium nitride layer 18b, the inventors have found the following findings. That is, in the test piece 15, titanium that tends to be surplus to nitrogen is released from the titanium nitride layer 18 having energy increased by the high-temperature thermal processing, and the released titanium passes through a crystal grain boundary of ruthenium in the ruthenium layer 19 to be precipitated on the ruthenium layer 19. Further, the precipitated titanium is bonded to nitrogen in nitrogen gas under an atmosphere of the high-temperature thermal processing, so that the upper titanium nitride layer 18b is formed above the ruthenium layer 19. As a result, the titanium nitride layer 18 that releases titanium is changed to the lower titanium nitride layer 18a in which titanium decreases, and titanium bonded to sufficient nitrogen from the atmosphere forms the upper titanium nitride layer 18b in which nitrogen is rich.

In addition, it is considered that the titanium nitride layer is changed by the high-temperature thermal processing to be stabilized. Further, a composition ratio of nitrogen to titanium in the lower titanium nitride layer 18a after the high-temperature thermal process was 0.6, and a composition ratio of nitrogen to titanium in the upper titanium nitride layer 18b after the high-temperature thermal process was 1.0. Therefore, it was considered that when the composition ratio of nitrogen to titanium is 0.6 or more and 1.0 or less, the titanium nitride layer is stabilized so as not to release titanium even when the high-temperature thermal processing is performed, and hence the composition ratio of nitrogen to titanium in the titanium nitride layer is not changed.

In addition, the inventors measured a composition ratio of nitrogen to titanium in the titanium nitride layer 21 of the test piece 20 after the high-temperature thermal processing. As a result, it was confirmed that the composition ratio of nitrogen to titanium in the titanium nitride layer 21 was changed to 1.0 from 1.2 before the high-temperature thermal processing (FIG. 6B). In other words, it was confirmed that in the test piece 20, nitrogen was relatively decreased by the high-temperature thermal processing in the titanium nitride layer 18 at a lower side of the ruthenium layer 19.

From the confirmed decrease in nitrogen in the titanium nitride layer 21, the inventors have found the following findings. That is, in the test piece 20, nitrogen that tends to be surplus to titanium is released from the titanium nitride layer 18 having energy increased by the high-temperature thermal processing so that nitrogen is relatively decreased. Further, it was considered that the released nitrogen passes through a crystal grain boundary of ruthenium in the ruthenium layer 19 and is exposed to an atmosphere of the high-temperature thermal processing from the ruthenium layer 19.

In addition, as described above, the composition ratio of nitrogen to titanium in the titanium nitride layer 21 is changed from 1.2 before the high-temperature thermal processing to 1.0 after the high-temperature thermal processing. Therefore, it was considered that since titanium is stabilized even when the composition ratio of nitrogen to titanium is 1.0 or more, nitrogen that tends to be surplus to titanium is merely released by the high-temperature thermal processing, and titanium is not released.

Further, it was considered that since the composition ratio of nitrogen to titanium in the titanium nitride layer 21 after the high-temperature thermal processing was 1.0, the titanium nitride layer is stabilized when the composition ratio of nitrogen to titanium is 1.0 or less, so that the composition ratio of nitrogen to titanium is not changed even when the high-temperature thermal processing is performed. These findings are the same as those obtained from the high-temperature thermal processing of the test piece 15.

In summary, when the composition ratio of nitrogen to titanium in the titanium nitride layer before the high-temperature thermal processing is 0.6 or more, the titanium nitride layer is stabilized, so that titanium is not released even when the high-temperature thermal processing is performed or nitrogen that tends to be surplus is merely released. As a result, titanium is not released. Further, when the composition ratio of nitrogen to titanium in the titanium nitride layer before the high-temperature thermal processing is 0.6 or more and 1.0 or less, the titanium nitride layer is stabilized, so that titanium is not released even when the high-temperature thermal processing is performed.

Accordingly, it was perceived that, in order to prevent the degradation in etching processability of the ruthenium layer by the high-temperature thermal processing and prevent titanium from existing in the ruthenium layer, the composition ratio of nitrogen to titanium in the titanium nitride layer before the high-temperature thermal processing is set to 0.6 or more, preferably 0.6 or more and 1.0 or less. Thus, the release of titanium from the titanium nitride layer is prevented.

In addition, the inventors manufactured a plurality of test pieces 15 and 20 while changing the thickness of the ruthenium layer 19, and measured a resistivity of the ruthenium layer 19 in each test piece 15 or 20 after the high-temperature thermal processing. FIG. 7 is a graph showing the resistivity of the ruthenium layer 19 in each test piece 15 or 20 after the high-temperature thermal processing. In the graph in FIG. 7, “TiN 0.4” represents the test piece 15, and “TiN 1.2” represents the test piece 20. Further, the horizontal axis in the graph of FIG. 7 represents the thickness of the ruthenium layer 19, and the vertical axis in the graph represents the resistivity of the ruthenium layer 19.

As shown in the graph in FIG. 7, at the same film thickness, the resistivity of the ruthenium layer in the test piece 20 is lower than that of the ruthenium layer 19 in the test piece 15. Further, as described above, while titanium exists in the ruthenium layer 19 of the test piece 15 after the high-temperature thermal processing, titanium does not exist in the ruthenium layer 19 of the test piece 20 after the high-temperature thermal processing. Therefore, the cause of the degradation of the resistivity of the ruthenium layer 19 by the high-temperature thermal processing is considered to be the face that the diffused titanium exists in the ruthenium layer 19.

Accordingly, it was perceived that, in order to prevent the degradation of the resistivity of the ruthenium layer 19 by the high-temperature thermal processing and prevent titanium from existing in the ruthenium layer, the composition ratio of nitrogen to titanium in the titanium nitride layer before the high-temperature thermal processing is set to 0.6 or more, preferably 0.6 or more and 1.0 or less. Thus, the release of titanium from the titanium nitride layer is prevented.

Further, in the graph in FIG. 7, even in both the test piece 15 and the test piece 20, the reason why the resistivity of the ruthenium layer 19 is degraded (improved) when the thickness of the ruthenium layer 19 increases is that scattering influence of electrons is reduced when the thickness of the ruthenium layer 19 increases.

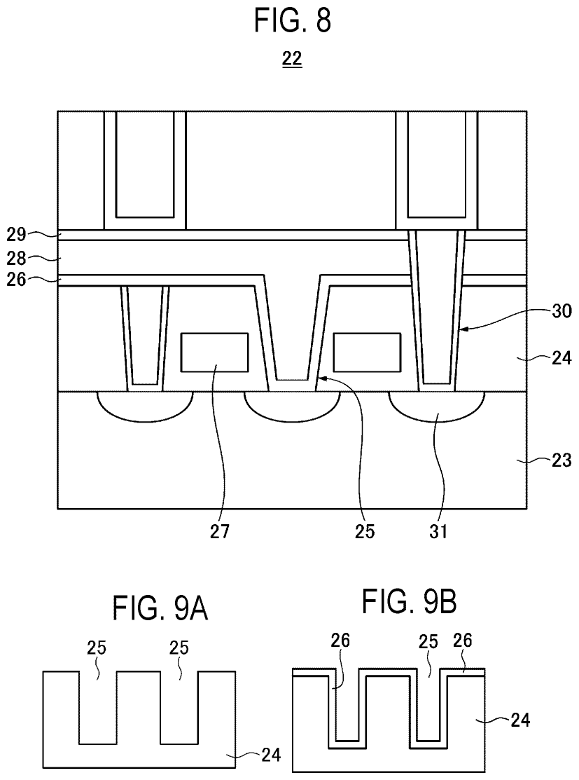

Next, an application of the technique according to the present disclosure will be described. FIG. 8 is a partial cross-sectional view schematically illustrating an example of a configuration of a DRAM as a semiconductor device, to which the technique according to the present disclosure is applied.

In FIG. 8, in a DRAM 22, a silicon dioxide film 24 as an interlayer insulating film is formed on a substrate 23 mainly made of p-type silicon. Further, a titanium nitride layer 26 as an adhesion layer is formed to cover the silicon dioxide film 24 and surfaces of a via-hole 25 formed in the silicon dioxide film 24. A wiring layer 27 as a word line is formed in the silicon dioxide film 24. Further, a ruthenium layer 28 (metal layer) as a bit line is formed to cover the titanium nitride layer 26. The ruthenium layer 28 is covered by a silicon nitride film 29. Further, a capacitor 30, which penetrates through the silicon dioxide film 24, the titanium nitride layer 26, the ruthenium layer 28, and the silicon nitride film 29 to reach the substrate 23, is formed. Further, the capacitor 30 comes into contact with an electrode portion 31 made of n-type silicon in the substrate 23.

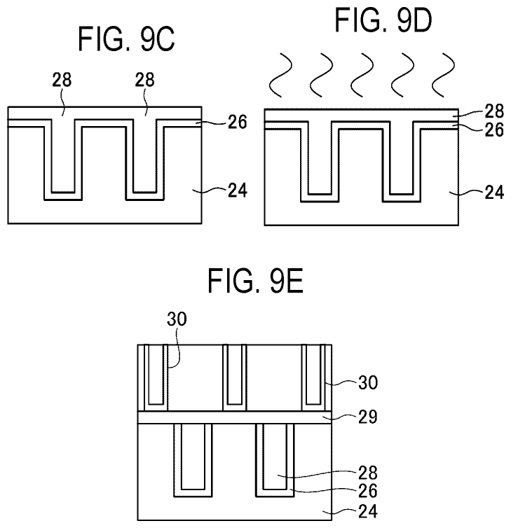

FIGS. 9A to 9E are process views illustrating some of a process of manufacturing the DRAM to which the technique according to the present disclosure is applied. First, a via-hole 25 is formed in a silicon dioxide film 24 by etching (FIG. 9A). Subsequently, the titanium nitride layer 26 is formed by PVD to cover a surface of the silicon dioxide film 24 or the via-hole 25 (FIG. 9B).

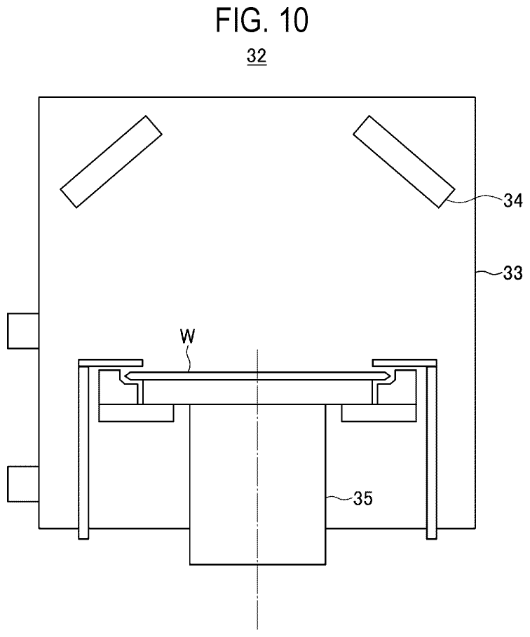

FIG. 10 is a view schematically illustrating a configuration of an example of a PVD apparatus for forming the titanium nitride layer 26. In FIG. 10, a PVD apparatus 32 includes a vacuum container 33, a target 34, a stage 35, and a plasma generator (not illustrated). The target 35 or the stage 35 is disposed in an interior of the vacuum container 33. A wafer W is placed on the stage 35. The target 34 has an annular shape, and is disposed at an upper portion of the interior of the vacuum container 33 to face the wafer W. In this embodiment, the target 34 is made of titanium.

In the PVD apparatus 32, the interior of the vacuum container 33 is depressurized by an exhaust device (not illustrated), and an argon (Ar) gas and a nitrogen gas are supplied at a predetermined flow rate ratio into the vacuum container 33. The argon gas or the nitrogen gas is excited by the plasma generator to be plasmarized. Argon ions in the plasma are attracted to the target 34 by a bias voltage applied to the target 34 to sputter the target 34. At this time, the target 34 releases titanium particles as sputter particles. The released titanium particles are ionized when passing through the plasma generated in the interior of the vacuum container 33. Further, titanium nitride is generated by reaction between the titanium ions with the nitrogen ions. The generated titanium nitride is attached to a surface of the wafer W to form the titanium nitride layer 26.

In this embodiment, a flow rate of the argon gas or the nitrogen gas is adjusted such that a composition ratio of nitrogen to titanium in the titanium nitride layer 26 becomes 0.6 or more, preferably 0.6 or more and 1.0 or less. In addition, a method of forming the titanium nitride layer 25 is not limited to PVD. The titanium nitride layer 26 may be formed using chemical vapor deposition (CVD) or atomic layer deposition (ALD).

Subsequently, the ruthenium layer 28 is formed by PVD to cover the titanium nitride 26. The above-described PVD apparatus 32 may be used even when forming the ruthenium layer 28. In the case of forming the ruthenium layer 28, the target 34 is made of ruthenium, and only the argon gas except for the nitrogen gas is supplied into the vacuum container 33. Further, the target 34 sputtered by the argon gas releases ruthenium particles. The ruthenium particles are ionized when passing through plasma to be attached to the surface of the wafer W. Accordingly, the ruthenium layer 28 is formed (FIG. 9C). In addition, a method of forming the ruthenium layer 28 is not limited to PVD. The ruthenium layer 28 may be formed using CVD or ALD.

Thereafter, a first thermal processing of heating the wafer W at, for example 600 degrees C. or higher, is performed (FIG. 9D). By the thermal processing, ruthenium grains (crystal grain boundary) of ruthenium in the ruthenium layer 28 grow, so that the ruthenium layer 28 is stabilized.

Subsequently, the titanium nitride layer 26 or the ruthenium layer 28, which exists on the surface of the wafer W, is removed by polishing the surface of the wafer W, using chemical mechanical polishing (CMP). Thereafter, the silicon nitride film 29 is formed on the surface of the wafer W, and the capacitor 30 or another film is formed (FIG. 9E). At this time, a second thermal processing of heating the wafer W at, for example, 800 degrees C., preferably 950 degrees C. or higher for one minutes or more, is performed.

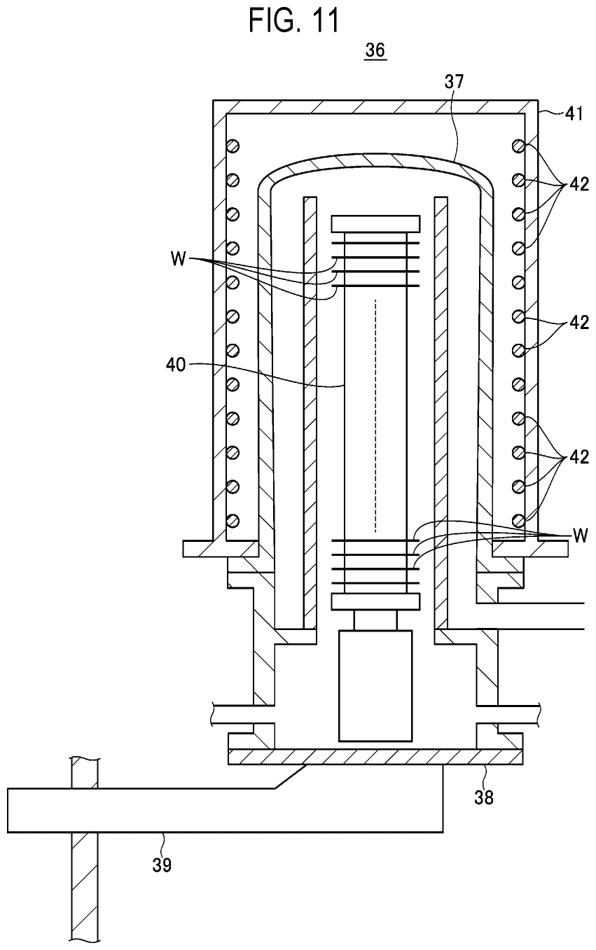

FIG. 11 is a view schematically illustrating a configuration of an example a thermal processing apparatus that performs the first thermal processing or the second thermal processing. In FIG. 11, a thermal processing apparatus 36 is a vertical furnace, and may simultaneously perform a thermal processing on a plurality of wafers W. The thermal processing apparatus 36 includes a reaction tube 37 that is a substantially cylindrical vacuum container along a length direction as a vertical direction. A bottom of the reaction tube 37 is open. Such an opening is closed by a cover 38. Accordingly, an interior of the reaction tube 37 is maintained airtightly. The cover 38 is configured to be raised and lowered between a rising position and a falling position by a boat elevator 39.

Further, a wafer boat 40 made of, for example, quartz, is placed on the cover 38. The wafer boat 40 horizontally holds the plurality of wafers W at predetermined intervals in the vertical direction. A heat insulator 41 is provided at a periphery of the reaction tube 37 to surround the reaction tube 37, and a heater 42 made of, for example, a resistance heating element, is provided on an inner wall of the heat insulator 41. The heater 42 heats the interior of the reaction tube 37 to perform a thermal processing on each wafer W. Further, when performing the thermal processing on each wafer W, a nitrogen gas is supplied to the interior of the reaction tube 37.

In addition, the thermal processing apparatus that performs the first thermal processing or the second thermal processing on the wafer W is not limited to the vertical furnace. For example, a rapid thermal processing (RTP) apparatus that uses a continuous lighting lamp to heat the wafer W, or a flash anneal apparatus that heats the wafer W by irradiating flash light onto the wafer W, may be used for the first thermal processing or the second thermal processing.

In the process of manufacturing the DRAM in FIGS. 9A to 9E, the titanium nitride layer 26 is also heated when the first thermal processing or the second thermal processing is performed. However, since the composition ratio of nitrogen to titanium in the titanium nitride layer 26 is 0.6 or more, preferably 0.6 or more and 1.0 or less, the titanium nitride layer 26 is stabilized or releases only nitrogen, so that titanium is not diffused into the ruthenium layer 28. As a result, although the first thermal processing or the second thermal processing is performed, the etching processability of the ruthenium layer 28 is not degraded, and the resistivity of the ruthenium layer 28 is not also be degraded.

According to Document (collectively written by H. Honjo, M. Niwa, K. Nishioka, T. V. A. Nguyen, H. Naganuma, Y. Endo, M. Yasuhira, S. Ikeda, and T. Endoh, entitled “Influence of Hard Mask Materials on the Magnetic Properties of Perpendicular MTJs With Double CoFeB/MgO Interface”, IEEE TRANSACTIONS ON MAGNETICS, VOL.56, NO.8, August 2020), it is known that when performing a thermal processing at 400 degrees C. for two hours or more, diffusion of titanium occurs in ruthenium in a cap layer from a hard mask of a titanium nitride layer, and hence a tunnel magneto resistance effect of a magnetic tunnel junction element is deteriorated (for example, see a graph in FIGS. 2A and 2B in the same Document).

Therefore, in a semiconductor device having a stacked structure of a titanium nitride layer and a ruthenium layer, when performing a thermal processing while maintaining a temperature of the titanium nitride layer at 400 degrees C. or higher for two hours or more, it is preferable that a composition ratio of nitrogen to titanium in the titanium nitride layer is set to 0.6 or more, preferably 0.6 or more and 1.0 or less. Accordingly, by preventing titanium in the titanium nitride layer from being diffused into the ruthenium layer due to the thermal processing, it is possible to suppress the degradation of the tunnel magneto resistance effect of the magnetic thermal junction element.

According to the present disclosure in some embodiments, it is possible to prevent a degradation in etching processability of a metal layer or a degradation in resistivity of the metal layer.

In the above, preferred embodiments of the present disclosure have been described. However, the present disclosure is not limited to the above-described embodiments, and various modifications and changes can be made within the spirit and scope of the present disclosure.

For example, in the above-described embodiments, the technique according to the present disclosure has been applied to the stacked structure of the titanium nitride layer and the ruthenium layer. However, when a crystal grain boundary exists in the metal layer in contact with the titanium nitride layer, titanium may be diffused into the metal layer from the titanium nitride layer, and hence the technique according to the present disclosure may be applied to a stacked structure of the titanium nitride layer and the metal layer having the crystal grain boundary. For example, a molybdenum (Mo) layer, a cobalt (Co) layer, and a tungsten (W) layer may correspond to the metal layer having the crystal grain boundary, and the technique according to the present disclosure may be applied to a stacked structure of such metal layers and the titanium nitride layer. Accordingly, by preventing diffusion of titanium into the metal layer from the titanium nitride layer, it is possible to suppress the degradation in etching processability of the metal layer or the degradation in resistivity of the metal layer.

What is claimed is:

1. A method of manufacturing a semiconductor device including an insulating layer, an adhesion layer composed of a titanium nitride, and a metal layer, the method comprising:
forming the adhesion layer on the insulating layer;
forming the metal layer on the adhesion layer; and
performing a thermal processing on the insulating layer, the adhesion layer, and the metal layer,
wherein, in the forming of the adhesion layer, a composition ratio of nitrogen to titanium in the titanium nitride constituting the adhesion layer is 0.6 or more.

2. The method of claim 1, wherein, in the forming of the adhesion layer, the composition ratio of the nitrogen to the titanium in the titanium nitride constituting the adhesion layer is 0.6 or more and 1.0 or less.

3. The method of claim 1, wherein, in the performing the thermal processing, temperatures of the insulating layer, the adhesion layer, and the metal layer are maintained at 400 degrees C. or higher for two hours or more.

4. The method of claim 1, wherein, in the performing the thermal processing, temperatures of the insulating layer, the adhesion layer, and the metal layer are maintained at 800 degrees C. or higher for one minute or more.

5. The method of claim 1, wherein, in the performing the thermal processing, at least the metal layer is exposed to a nitrogen atmosphere.

6. The method of claim 1, wherein the metal layer is composed of a metal having a crystal grain boundary.

7. The method of claim 6, wherein the metal having the crystal grain boundary is one selected from a group consisting of tungsten, molybdenum, cobalt, and ruthenium.

8. An apparatus for manufacturing a semiconductor device including an insulating layer, an adhesion layer composed of titanium nitride, and a metal layer, wherein the adhesion layer is formed such that a composition ratio of nitrogen to titanium in the titanium nitride is 0.6 or more.

9. The apparatus of claim 8, wherein the adhesion layer is formed such that the composition ratio of the nitrogen to the titanium in the titanium nitride is 0.6 or more and 1.0 or less.

10. The apparatus of claim 8, wherein a thermal processing is performed on the insulating layer, the adhesion layer, and the metal layer.

11. A semiconductor device including an insulating layer, an adhesion layer composed of titanium nitride, and a metal layer,
wherein the insulating layer, the adhesion layer, and the metal layer are sequentially stacked one above another, and
wherein a composition ratio of nitrogen to titanium in the titanium nitride constituting the adhesion layer is 0.6 or more.

12. The semiconductor device of claim 11, wherein the composition ratio of the nitrogen to the titanium in the titanium nitride constituting the adhesion layer is 0.6 or more and 1.0 or less.

13. The semiconductor device of claim 11, wherein the semiconductor device is a DRAM.
